(19) United States
(12) Patent Application Publication
(10) Pub. No.: US 2004/0109289 A1
(43) Pub. Date: Jun. 10, 2004

(54) Combination structure of heat sink and cooling fan

(76) Inventor: Pi-Yun Lin, Taipei (TW)

Correspondence Address: BIRCH STEWART KOLASCH & BIRCH, PO BOX 747, FALLS CHURCH, VA, 22040-0747, US

(21) Appl. No.: 10/314,297

(22) Filed: Dec. 9, 2002

(51) Int. Cl. H05K 7/20

(52) U.S. Cl. 361/695; 165/121; 415/213.1

(57) ABSTRACT

A heat sink mainly comprises a plurality of fin-pieces, at least a heat-conductive duct, and a heat-conductive block, in which each fin-piece is perforated to form two through holes or more. When assembling the heat sink, first the fin-pieces are stacked one on another to form a heat-sink base, then the front end of the heat-conductive duct is sintered or tightly fixed in the through holes and the rear end is sintered or tightly fixed in the heat-conductive block to complete the construction. The cooling fan is laid in the manner that its axial direction is parallel to the normal of the fin-pieces rested on the heat-sink base, such that the cooling fan can blow air directly into the heat-sink base.

### FIELD OF THE INVENTION

This invention relates to a combination structure of heat sink and cooling fan, particularly to a heat-dissipation structure for chips, in which a heat-conductive block is arranged to absorb heat of the chips directly and conduct it through a heat-conduction mechanism to a heat-sink base formed by stacking a plurality of fin-pieces together so that the windage and noise can be lessened because lack of the angle of attack when air is blown into the heat-sink base to collide against the fin-pieces thereof.

### BACKGROUND OF THE INVENTION

A generic conventional heat sink shown in FIG. 4 is composed of fin-pieces (6), heat-conductive ducts (8), and a heat-conductive block (9), in which a lateral plate having a fastening piece and a snap hole is arranged on and beneath the fin-pieces (6) and several through holes are formed in a lateral wall of the heat-conductive block (9). When assembling, the fin-pieces (6) confined by the lateral plates are aggregated one piece after another to form a heat-sink base (7) and buckled together with the fastening piece and the snap hole to form a jointing portion (71) for fixing the fin-pieces (6) on the heat-sink base (7). Then the front face of the fin-pieces (6) are punched to provide through holes for guiding and sticking, usually by sintering, the front end of the heat-conductive ducts (8), and finally, the rear end of the heat-conductive ducts (8) are probed in the lateral wall of the heat-conductive block (9) and sintered to complete the assembling job.

In using such a conventional heat sink, the heat generated from a chip is absorbed by the heat-conductive block and transferred through the heat-conductive ducts to reach the heat-sink base comprising fin-pieces, and at this time, the wind come from a cooling fan would collide against the fin-pieces of the heat-sink base to make a relatively great noise.

### SUMMARY OF THE INVENTION

The primary objective of this invention is to provide a combination structure of heat sink and cooling fan, in which no angle of attack against airflow is formed on a fin-piece by adjusting the orientation of the fin-piece so that noise brought about by blowing air from a cooling fan into a heat-sink base to collide against fin-pieces can be lessened significantly.

In order to achieve abovesaid objective, a heat sink of this invention comprises a plurality of fin-pieces, at least a heat-conductive duct, and a heat-conductive block, in which each fin-piece is perforated to form two through holes or more. When assembling the heat sink, first the fin-pieces are stacked one on another to form a heat-sink base, then the front end of the heat-conductive duct is sintered or tightly fixed in the through holes and the rear end is sintered or tightly fixed in the heat-conductive block to complete the construction. Moreover, the cooling fan is laid in the manner that its axial direction is parallel to the normal of the fin-pieces rested on the heat-sink base, such that the cooling fan can blow air directly into the heat-sink base.

The improvements made according to this invention include: lengthening the fin-pieces; sticking the front end of the heat-conductive ducts to the through holes in the fin-pieces to thus enlarge the contact area of the ducts; and stacking the fin-pieces together to form a heat-sink base; such that the noise incurred by blowing air from the cooling fan into the heat-sink base can be significantly weakened.

For more detailed information regarding advantages or features of this invention, at least an example of preferred embodiment will be fully described below with reference to the annexed drawings.

### BRIEF DESCRIPTION OF THE DRAWINGS

The related drawings in connection with the detailed description of this invention to be made later are described briefly as follows, in which:

FIG. 1 is an exploded view of a heat sink of this invention in three dimensions;

FIG. 2 is an assembled view of the heat sink of this invention in three dimensions;

FIG. 3 is a schematic view showing an embodiment of heat sink and cooling fan of this invention; and

FIG. 4 shows an assembled conventional heat sink in three dimensions.

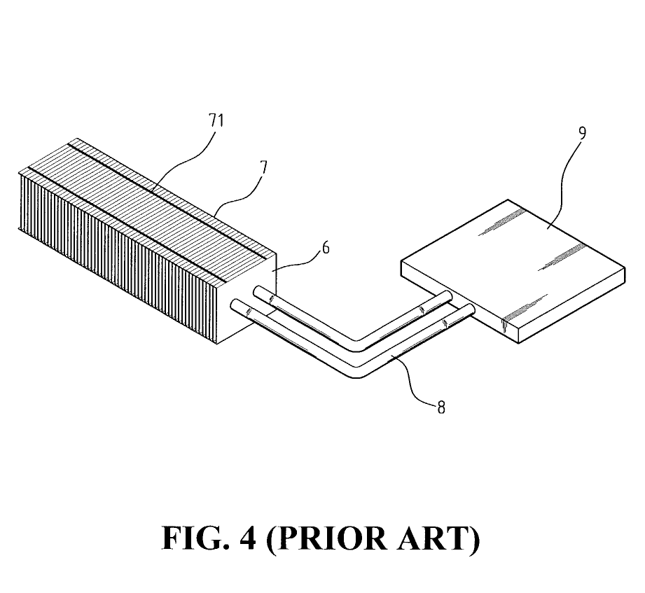

### DETAILED DESCRIPTION OF THE INVENTION

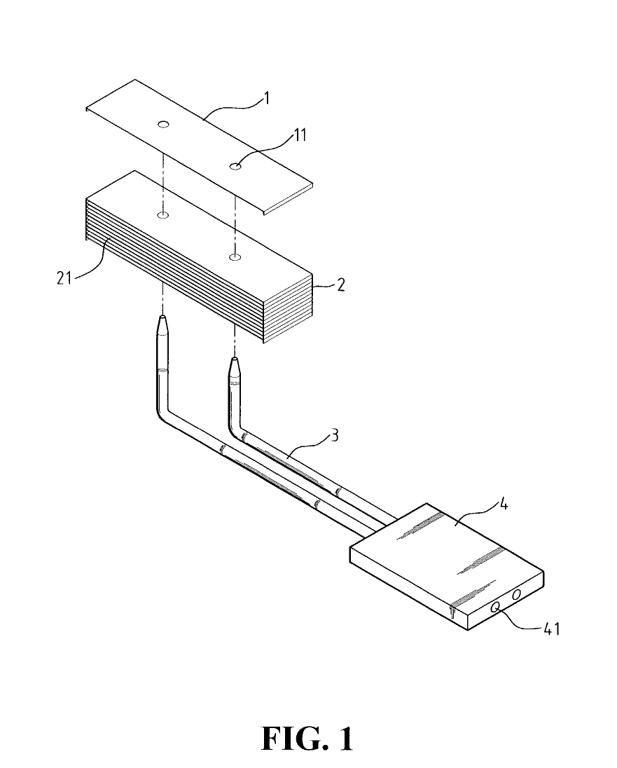

FIG. 1 shows an exploded view of heat sink of this invention in three dimensions. As shown in FIG. 1, a heat sink of this invention comprises a plurality of fin-pieces (1), a heat-conductive duct (3), and a heat-conductive block (4), in which the fin-piece (1) could be formed in any of a rectangle, a circle, or a polygon, etc.; and at least a heat-conductive duct (3) is provided to penetrate through a heat-sink base (2) and extend in an arbitrary direction to contact with the heat-conductive block (4) having several lateral through holes.

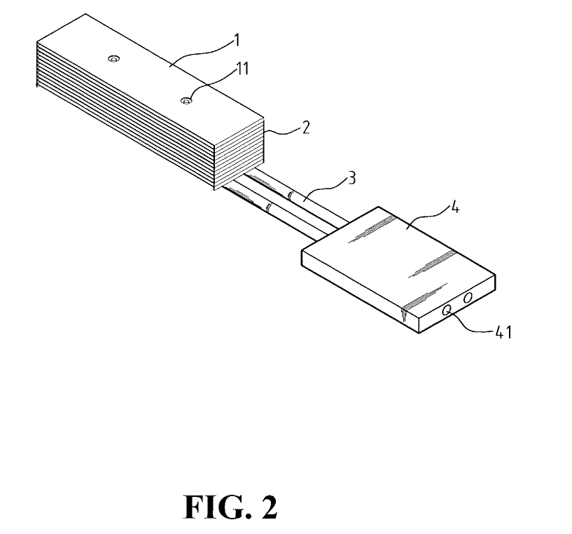

With reference to FIG. 2—a three-dimensional view of an assembled heat sink of this invention (also with cross-reference to FIG. 1), for assembling a heat sink of this invention, the front face of each fin-piece (1) is perforated to form two properly spaced parallel holes (11), then the fin-pieces (1) are stacked one after another from the bottom to the top to form the heat-sink base (2), in which all the holes (11) in respective rows are aligned flush. The procedure is then to hold a couple of heat-conductive ducts (3) and allow their front ends to penetrate and stay in the holes (11) of the fin-pieces (1) of the heat-sink base (2) for being sintered or tightly fixed to combine the heat-conductive ducts (3) and the heat-sink base (2) together. Finally, the rear end of the heat-conductive ducts (3) are placed in the lateral through holes (41) of the heat-conductive block (4) for being sintered or tightly fixed to connect the heat-conductive ducts (3) with the heat-conductive block (4) to hence have an improved integral heat-sink structure accomplished.

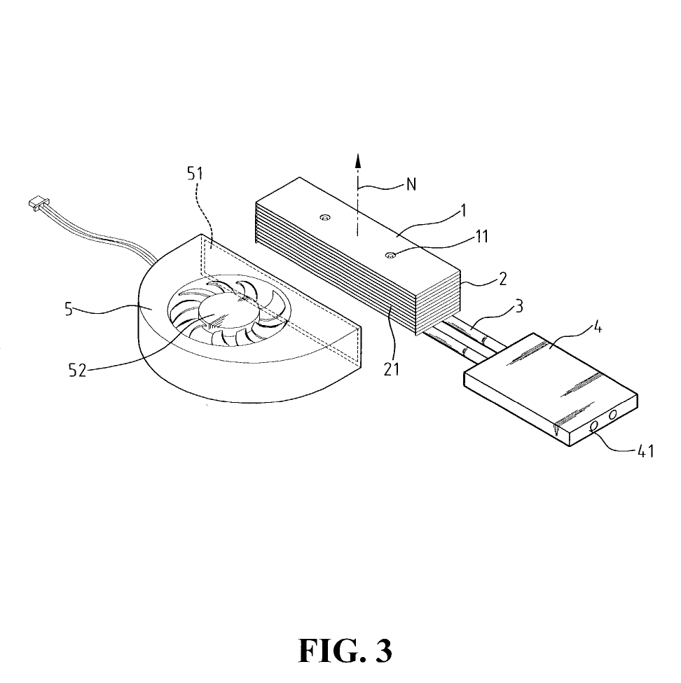

Referring to a schematic view of an embodiment of heat sink and cooling fan of this invention shown in FIG. 3 (also to FIG. 1), an air-outlet (51) of a cooling fan (5) is placed in front of a lateral heat-dissipation piece (21) of the heat-sink base (2), and meanwhile, the spindle (52) of the cooling fan (5) is parallel to the normal (N) of the heat-dissipation piece (21). The heat-conductive block (4) is rested on a chip (not shown). Because there is no angle of attack established between wind and the fin-piece (1) of the heat-sink base (2), therefore, the noise incurred when air is blown from the cooling fan (5) into the heat-dissipation pieces

of the heat-sink base (2) to collide against the fin-piece (1) can be lowered significantly even by 3 db.

In the above described, at least one preferred embodiment has been described in detail with reference to the drawings annexed, and it is apparent that numerous changes or modifications may be made without departing from the true spirit and scope thereof, as set forth in the claims below.

What is claimed is:

1. A combination structure of heat sink and cooling fan, comprising:
a plurality of fin-pieces;
a heat-sink base;
two heat-conductive ducts or more; and
a heat conductive block;
in which the normal of the fin-pieces on said heat-sink base is parallel to the axial direction of a cooling fan.
